(19) United States
(12) Patent Application Publication
(10) Pub. No.: US 2008/0289565 A1
(43) Pub. Date: Nov. 27, 2008

(54) Rescue whistle

(76) Inventor: Hsiao-Chi Lin, Taipei City (TW)

Correspondence Address: Troxell Law Office Pllc;Suite 1404, 5205 Leesburg Pike, Falls Church, VA, 22041, US

(21) Appl. No.: 11/882,074

(22) Filed: Jul. 30, 2007

(30) Foreign Application Priority Data
May 25, 2007 (TW) 096208572

(51) Int. Cl. G10K 5/00; G11C 5/00

(52) U.S. Cl. 116/137 R; 365/52

(57) ABSTRACT

A rescue whistle, end surfaces of two ends of which are respectively concaved with a holding space, a circuit board main body at one end of a flash drive storage unit is positioned within one of the holding spaces, and a USB connector at another end of the flash drive storage unit protrudes outside the holding space. A whistle is connected to the other holding space, forming a sealed space, within which is deposited a strip of paper with health information on an individual written thereon. Accordingly, when an accident occurs, rescue workers can access the pieces of health information on the individual stored in the flash drive storage unit, or refer to the health information of the individual written on the strip of paper, thereby facilitating carrying out the most appropriate first aid and care.

### BACKGROUND OF THE INVENTION

(a) Field of the Invention

The present invention relates to a rescue whistle, and more particularly to a whistle which stores a number of pieces of data in a USB (Universal Serial Bus) flash drive and information written on paper on the health status (including medical history) of an individual, thereby providing reference information when administering first aid in a life-threatening emergency.

(b) Description of the Prior Art

Because excessively high risks are often taken when mountaineering or during other outdoor activities (rock climbing in particular), resulting in danger to self or others, thus, in order to prevent harm to life resulting from the danger, a whistle is normally carried that can be blown to call for help in an emergency and summon companions close by for first aid and care.

However, whistles of prior art are only able to summon companions close by for first aid and care, and when companions arrive to rescue those in need, they have no way of knowing the health status and medical history (for example: heart disease, blood-group, medication allergies, and so on) of those being rescued, and is thus difficult to determine what first aid to administer, resulting in delaying first aid treatment. In particular, when those being rescued are injured, or when unconsciousness or unable to explain their personal health status (including medical history), then mistakes in diagnosis are very easily made and the wrong first aid administered.

### SUMMARY OF THE INVENTION

Hence, in light of the shortcomings of the aforementioned prior art, the inventor of the present invention, having accumulated knowhow and manufacturing experience of various rescue products, attentively researched various methods to resolve such drawbacks, which, following continuous research and improvements, culminated in the design of a completely new rescue whistle of the present invention.

A primary objective of the present invention is to provide a rescue whistle which stores a number of pieces of data in a USB flash drive and information written on paper on the health status (including medical history) of an individual, thereby providing reference information when administering first aid in a life-threatening emergency.

According to the aforementioned objective, the rescue whistle of the present invention is configured with a tubular main body, end surfaces of two ends of which are respectively concaved with a holding space, wherein one of the holding spaces enables a flash drive storage unit to penetrate and be held therein, and a whistle is installed in the other holding space. A circuit board main body at one end of the flash drive storage unit is positioned within one of the holding spaces, and a USB connector at another end of the flash drive storage unit protrudes outside the holding space. The flash drive storage unit prestores a number of pieces of data, including health status and medical history on an individual. A hollow connecting portion is located on the whistle, and a periphery of the connecting portion is configured with an external screw thread, and an inner periphery of the other holding space of the main body is configured with a mutually matching internal screw thread, thereby enabling the external screw thread of the connecting portion to screw into the internal screw thread of the holding space, thus connecting the whistle to the other end of the main body and enabling the other holding space to form a sealed space, within which is deposited a strip of paper with the health status and medical history of an individual written thereon. Accordingly, when a life threatening emergency occurs, then the whistle can be used to call for help. Furthermore, when rescue workers arrive, they can access the pieces of data on the health status and medical history of the individual stored in the flash drive storage unit, or refer to the health status and medical history information of the individual written on the strip of paper, thereby facilitating carrying out the most appropriate first aid and care.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 shows an elevational external view of a rescue whistle of the present invention.

FIG. 2 shows a first structural schematic view of the rescue whistle of the present invention.

FIG. 3 shows a second structural schematic view of the rescue whistle of the present invention.

### DETAILED DESCRIPTION OF THE PREFERRED EMBODIMENTS

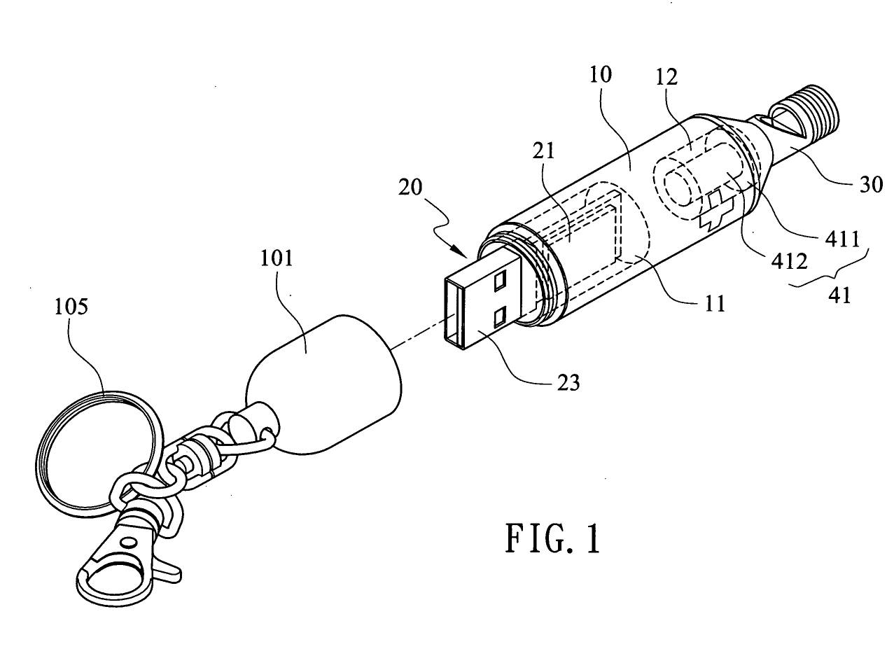

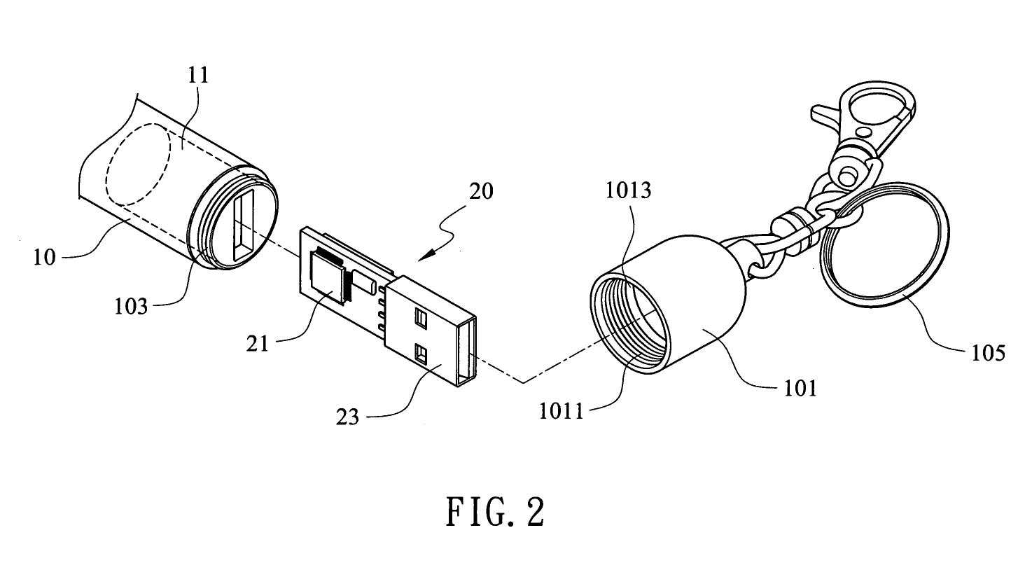

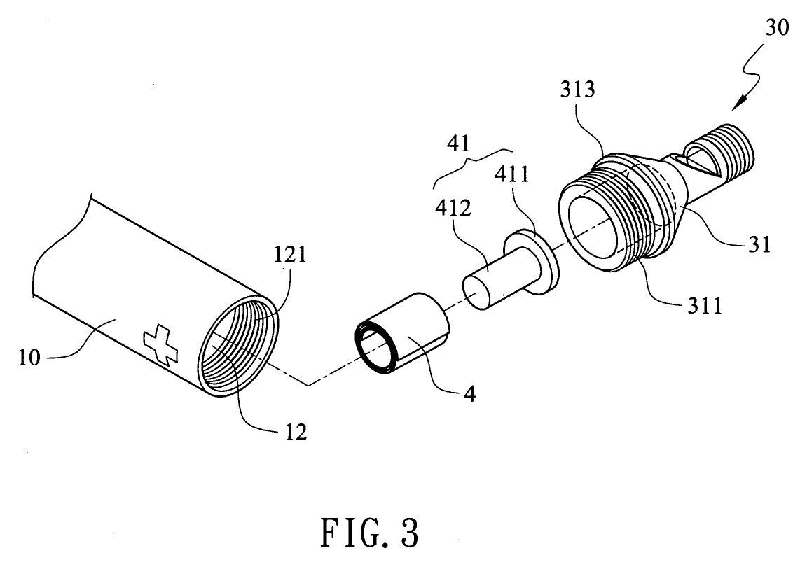

Referring to FIGS. 1, 2 and 3, which show a rescue whistle of the present invention, comprising a tubular main body 10, end surfaces of two ends of which are respectively concaved with holding spaces 11, 12, wherein the holding space 11 enables a flash drive storage unit 20 to penetrate and be held therein, and a whistle 30 is installed in the holding space 12. A circuit board main body 21 at one end of the flash drive storage unit 20 is positioned within the holding space 11, and a USB connector 23 at another end of the flash drive storage unit 20 protrudes outside the holding space 11. The flash drive storage unit 20 prestores a number of pieces of data, including health status and medical history (for example: heart disease, blood-group, medication allergies, and so on) on an individual.

A hollow connecting portion 31 is located on the whistle 30; a periphery of the connecting portion 31 is configured with an external screw thread 311, and an inner periphery of the holding space 12 of the main body 10 is configured with a mutually matching internal screw thread 121, thereby enabling the external screw thread 311 of the connecting portion 31 to screw into the internal screw thread 121 of the holding space 12, thus connecting the whistle 30 to the other end of the main body 10 and enabling the holding space 12 to form a sealed space, within which is deposited a strip of paper 4 with the health status and medical history of an individual (for example: heart disease, blood-group, medication allergies, and so on) written thereon. Moreover, a paper strip mount 41 is disposed within the sealed space, and the paper strip mount 41 is provided with a circular base plate 411. A bottom surface of the base plate 411 covers a bottom end of the whistle 30, and a cylinder 412 is perpendicularly located on the center of a top end of the base plate 411, thereby enabling the rolled up strip of paper 4 to be mounted onto the cylinder 412 of the paper strip mount 41.

Accordingly, when a life threatening emergency occurs, then the whistle 30 can be used to call for help. Furthermore, when rescue workers arrive, they can use a computer to access the pieces of data stored in the flash drive storage unit 20 on the health status and medical history (for example: heart disease, blood-group, medication allergies, and so on) of the individual, or refer to the health status and medical history information (for example: heart disease, blood-group, medication allergies, and so on) of the individual written on the strip of paper 4, thereby facilitating carrying out the most appropriate first aid and care in the shortest time.

Referring again to FIGS. 1, 2 and 3, a watertight gasket 313 is mounted on the external screw thread 311 of the whistle 30, thereby enabling providing a more tight seal when the whistle 30 is screwed into the other holding space 12 of the main body 10, and providing a waterproof function.

Referring again to FIGS. 1, 2 and 3, an outer cover 101 is mounted on the flash drive storage unit 20 of the main body 10, which enables the outer cover 101 to cover the USB connector 23 of the flash drive storage unit 20, and thereby protect the USB connector 23. An inner periphery of the outer cover 101 is configured with an internal screw thread 1011, and a periphery of the main body 10 is configured with a matching external screw thread 103, thereby enabling the internal screw thread 1011 of the outer cover 101 to screw onto the external screw thread 103 of the main body 10, and thus cover the USB connector 23 of the flash drive storage unit 20 with the outer cover 101.

Referring again to FIGS. 1, 2 and 3, a watertight gasket 1013 is disposed within the outer cover 101, thereby enabling providing a more tight seal when the outer cover 101 is screwed onto the main body 10, and providing a waterproof function. In addition, a key ring 105 can be fitted to the outer cover 101, thereby facilitating portability and attachment of keys.

In conclusion, the rescue whistle of the present invention is assuredly provided with an Innovative structure not found in prior art. Moreover, products having a similar structure to that of the present invention have not been seen in any publication or in the market, the present invention is thus provided with undoubted originality. In addition, the present invention is provided with unique characteristics and functionality that are without comparison in prior art. Hence, the incomparable advancement of the present invention clearly complies with essential elements as required for a new patent application. Accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A rescue whistle, comprising:
a tubular main body, end surfaces of two ends of which are respectively concaved with a holding space;
a flash drive storage unit, a circuit board main body located at one end of which is positioned within one of the holding spaces, and a USB (Universal Serial Bus) connector at another end of the circuit board main body protrudes outside the holding space; the flash drive storage unit prestores a number of pieces of data on the health status and medical history of an individual; and
a whistle configured with a hollow connecting portion; a periphery of the connecting portion is configured with an external screw thread, and an inner periphery of the other holding space of the main body is configured with a mutually matching internal screw thread, thereby enabling the external screw thread of the connecting portion to screw into the internal screw thread of the holding space, thus connecting the whistle to the other end of the main body and enabling the holding space to form a sealed space, within which is deposited a strip of paper with health status and medical history of an individual written thereon.

2. The rescue whistle according to claim 1, wherein a watertight gasket is mounted on the external screw thread of the whistle, thereby providing a more tight seal when the whistle is screwed into the other holding space of the main body, and providing a waterproof function.

3. The rescue whistle according to claim 1, wherein an outer cover is mounted on the flash drive storage unit of the main body, which enables the outer cover to cover the USB connector of the flash drive storage unit, and thereby protect the USB connector.

4. The rescue whistle according to claim 3, wherein an inner periphery of the outer cover is configured with an internal screw thread, and a periphery of the main body is configured with a matching external screw thread, thereby enabling the internal screw thread of the outer cover to screw onto the external screw thread of the main body, and thus cover the USB connector of the flash drive storage unit with the outer cover.

5. The rescue whistle according to claim 4, wherein a watertight gasket is disposed within the outer cover, thereby providing a more tight seal when the outer cover is screwed onto the main body, and providing a waterproof function.

6. The rescue whistle according to claim 5, wherein a key ring is fitted to the outer cover.

7. The rescue whistle according to claim 1, wherein a paper strip mount is disposed within the sealed space formed by the other holding space, the paper strip mount is provided with a circular base plate, a bottom surface of which covers a bottom end of the whistle, and a cylinder is perpendicularly located on the center of a top end of the base plate, thereby enabling the rolled up strip of paper to be mounted onto the cylinder of the paper strip mount.
